(19) United States
(12) Patent Application Publication
(10) Pub. No.: US 2026/0182163 A1
(43) Pub. Date: Jun. 25, 2026

(54) DISPLAY PANEL

(71) Applicant: LG Display Co., Ltd., Seoul (KR)

(72) Inventors: Sun Young CHOI, Paju-si (KR); Dong Chae SHIN, Paju-si (KR); Mi Jin JEONG, Paju-si (KR); Ju Hee JUNG, Paju-si (KR)

(73) Assignee: LG Display Co., Ltd., Seoul (KR)

(21) Appl. No.: 19/282,918

(22) Filed: Jul. 28, 2025

(30) Foreign Application Priority Data
Dec. 24, 2024 (KR) 10-2024-0196086

(51) Int. Cl. H10K 59/124; H10K 59/121; H10K 102/00

(52) U.S. Cl. CPC H10K 59/124; H10K 59/1213; H10K 2102/351

(57) ABSTRACT

A display panel is provided. The display panel includes a substrate including an active area and a non-active area. A subpixel in the active area includes a light emitting device, a driving transistor configured to supply a driving current to the light emitting device, and a switching transistor electrically connected to the driving transistor. Each of the driving and switching transistors includes a gate electrode and a semiconductor layer including oxide. A first upper interlayer insulation layer is on the semiconductor layer of each transistor, and a second upper interlayer insulation layer is on the first upper interlayer insulation layer. The thickness of the first upper interlayer insulation layer on the semiconductor layer of the switching transistor is different from that on the semiconductor layer of the driving transistor. This structure allows the display panel to accommodate differing electrical characteristics required by the switching and driving transistors in each subpixel.

### CROSS-REFERENCE TO RELATED APPLICATIONS

This application claims the benefit of the Korean Patent Application No. 10-2024-0196086 filed on Dec. 24, 2024, which is hereby incorporated by reference as if fully set forth herein.

### BACKGROUND

### Technical Field

The present disclosure relates to a display panel.

### Description of the Related Art

In televisions (TVs), monitors, smartphones, tablet personal computers (PCs), and notebook computers, display apparatuses displaying an image are being used in various modes and types.

Display apparatuses include a display panel, which includes a plurality of light emitting devices for implementing an image and a transistor for controlling an operation of each of the light emitting devices or an operation of a liquid crystal, and intactly display an image which is to be displayed through the plurality of light emitting devices or the liquid crystal.

Display apparatuses include a plurality of pixels each including a light emitting device, and moreover, include a plurality of driving and switching elements for driving and controlling the light emitting device included in each of the pixels. The driving and switching elements may each be configured as a transistor.

Recently, various research and developments for enhancing the performance and reliability of transistors are being done.

### BRIEF SUMMARY

The disclosure relates to a display panel that uses a differentiated interlayer structure to optimize transistor performance based on their function and the color of the subpixel. By adjusting the thickness and material composition of the upper interlayer insulation layers, such as silicon oxide and silicon nitride, the structure controls the diffusion of hydrogen into the oxide semiconductor layers. This approach allows the switching transistors to maintain longer channel lengths and stable threshold voltages, while driving transistors for blue subpixels achieve higher on current characteristics, and those for green subpixels exhibit improved gray level control through enhanced subthreshold swing.

The structure also includes a multilayer buffer beneath the transistors, composed of dielectric materials with different properties, to adjust capacitance and further support desired electrical characteristics. These targeted modifications across the subpixel regions enable consistent and reliable transistor behavior, reduce power consumption, improve energy efficiency, and extend device durability.

For example, embodiments of the present disclosure provide a display panel where an interlayer structure is enhanced to be suitable for a desired characteristic of each transistor.

Embodiments of the present disclosure provide a display panel which is suitable for a desired characteristic of each switching transistor and driving transistor.

Embodiments of the present disclosure provide a display panel which is suitable for a desired characteristic of a switching transistor in each subpixel.

Embodiments of the present disclosure provide a display panel which is suitable for a desired characteristic of a driving transistor requiring relatively stable gray expression in each subpixel.

Embodiments of the present disclosure provide a display panel which is suitable for a desired characteristic of a driving transistor requiring a relatively high on current (Ion) characteristic in each subpixel.

Embodiments of the present disclosure may enhance the reliability of transistors and a display panel and may decrease power consumption, thereby implementing environment, social, and governance (ESG).

A display panel according to an embodiment of the present disclosure includes a substrate including an active area and a non-active area, a driving transistor configured to supply a driving current to a light emitting device disposed in a subpixel of the active area and including a gate electrode and a semiconductor layer including oxide, a switching transistor disposed in the subpixel, electrically connected to the driving transistor, and including a gate electrode and a semiconductor layer including oxide, a first upper interlayer insulation layer disposed on the semiconductor layer of each of the driving transistor and the switching transistor, and a second upper interlayer insulation layer disposed on the first upper interlayer insulation layer, wherein a thickness of the first upper interlayer insulation layer disposed on the semiconductor layer of the switching transistor differs from a thickness of the first upper interlayer insulation layer disposed on the semiconductor layer of the driving transistor.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a diagram for describing an embodiment of a display apparatus applicable to the present disclosure;

FIG. 2 is a diagram for describing an embodiment of a pixel equivalent circuit of a subpixel applicable to a display apparatus according to the present disclosure;

FIG. 3 is a diagram for describing an embodiment of an interlayer structure of a display panel including a switching transistor and a driving transistor according to a first embodiment of the present disclosure;

FIG. 4 is a diagram for describing a hydrogen concentration in a semiconductor layer of each of a switching transistor and first and second driving transistors illustrated in FIG. 3;

FIG. 5 is a diagram for describing a channel valid length difference and a threshold voltage (Vth) difference between a switching transistor and first and second driving transistors improved according to a second embodiment of the present disclosure;

FIG. 6 is a diagram for describing an S-factor and a characteristic graph of a driving transistor improved according to a first embodiment of the present disclosure;

FIGS. 7 and 8 are diagrams for describing an embodiment of an interlayer structure of a display panel including a switching transistor and a driving transistor according to a second embodiment of the present disclosure;

FIG. 9 is a diagram for describing an embodiment of an interlayer structure of a display panel including a transistor provided in a non-active area compared to a transistor provided in an active area, according to a first embodiment of the present disclosure; and

FIG. 10 is a diagram for describing an embodiment of an interlayer structure of a display panel including a low temperature polycrystalline silicone (LTPS) transistor capable of being further provided in a non-active area, according to an embodiment of the present disclosure.

### DETAILED DESCRIPTION

Hereinafter, embodiments will be described in detail with reference to the accompanying drawings.

Like reference numerals refer to like elements.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In the present disclosure, when an arbitrary element (or a region, a layer, a portion, etc.) is described as “being on,” “connected,” or “coupled,” this may denote that the arbitrary element may be directly connected/coupled to another element, or a third element may be disposed therebetween.

To elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

The term “and/or” may include all of one or more combinations capable of being defined by relevant elements.

Terms like a first and a second may be used to describe various elements, but the elements should not be limited by the terms. The terms may be used only as object for distinguishing an element from another element. For example, without departing from the spirit and scope of the inventive concept, a first element may be referred to as a second element, and similarly, the second element may be referred to as the first element. The terms of a singular form may include plural forms unless referred to the contrary.

The terms “under,” “below,” “on,” and “above” may be used to describe a correlation between elements illustrated in the drawings. The terms may be a relative concept and may be described with respect to a direction illustrated in the drawings. For example, unless “just” or “direct” is used, one or more other elements between two elements may be disposed. Spatially relative terms “below,” “beneath,” “lower,” “above,” and “upper” may be used herein for easily describing a relationship between one device or elements and other devices or elements as illustrated in the drawings. Therefore, for example, “under” and “lower” may be opposite to “on” and “upper” with respect to a first element.

It should be understood that spatially relative terms are terms including different orientations of elements in use or operation, in addition to the orientation illustrated in the drawings. For example, if a device in the drawings is turned over, elements described as being on the “below” or “beneath” sides of other elements may be placed on “above” sides of the other elements. Therefore, the exemplary term “lower” may include both orientations of “lower” and “upper”. Likewise, the exemplary term “above” or “upper” may include both orientations of above and below.

It should be understood that the meaning of “include,” “comprise,” “including,” or “comprising,” specifies a property, a region, a fixed number, a step, a process, an element and/or a component, but does not exclude other properties, regions, fixed numbers, steps, processes, elements and/or components.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other, or may be carried out together in co-dependent relationship.

Hereinafter, a display apparatus according to an embodiment of the present disclosure will be described with reference to the accompanying drawings.

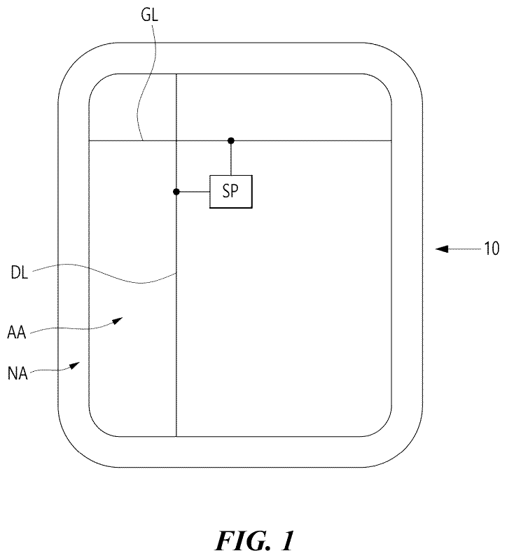

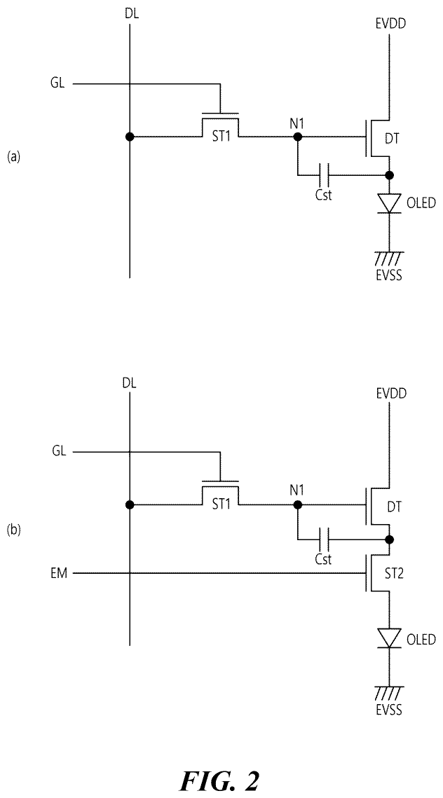

FIG. 1 is a diagram for describing an embodiment of a display apparatus applicable to the present disclosure. FIG. 2 is a diagram for describing an embodiment of a pixel equivalent circuit of a subpixel SP applicable to a display apparatus according to the present disclosure.

Referring to FIGS. 1 and 2, a display apparatus according to an embodiment of the present disclosure may include a display panel 10, and the display panel 10 may include an active area AA and a non-active area NA.

The active area AA may be an area which displays an image. A plurality of subpixels SP may be disposed at respective intersections of gate lines GL and data lines DL in the active area AA of the display panel 10, and the active area AA may display an image by using the plurality of subpixels SP. One subpixel SP is illustrated in the active area AA in FIG. 1, but a plurality of subpixels SP including one subpixel SP may be disposed in the active area AA.

The plurality of subpixels SP may include a subpixel SP which emits lights of different colors. For example, a subpixel SP emitting red (R) light, a subpixel SP emitting green (G) light, and a subpixel SP emitting blue (B) light may be grouped to configure one unit pixel, and each unit pixel may implement various colors by mixing different colors of lights emitted from subpixels SP.

An area where the plurality of subpixels SP are disposed may be the active area AA, and an area other than the active area AA may be the non-active area NA.

The non-active area NA may be disposed in an edge region surrounding the active area AA which displays an image. At least one driver for driving the plurality of subpixels SP may be disposed in the non-active area NA. The driver may be a gate in panel (GIP) type.

Various additional elements for driving the subpixels SP of the active area AA may be further disposed in the non-active area NA.

At least one subpixel SP among a plurality of subpixels SP, for example, as illustrated in part (a) or (b) of FIG. 2, may include a first switching transistor ST1, a driving transistor DT, a capacitor Cst, and a light emitting device OLED.

A first electrode (for example, a drain electrode) of the first switching transistor ST1 may be electrically connected to a data line DL, a second electrode (for example, a source electrode) thereof may be electrically connected to a first node N1, and a gate electrode of the first switching transistor ST1 may be electrically connected to a gate line GL. The first switching transistor ST1 may transfer a data signal, supplied through the data line DL, to the first node N1 in response to a scan signal supplied through the gate line GL.

The capacitor Cst may be electrically connected to the first node N1 and may be charged with a voltage applied to the first node N1.

A first electrode (for example, a drain electrode) of the driving transistor DT may be supplied with a high-level driving voltage EVDD, and a second electrode (for example, a source electrode) thereof may be electrically connected to a first electrode (for example, an anode electrode) of the light emitting device OLED. The driving transistor DT may control a magnitude of a driving current flowing in the light emitting device OLED, based on a voltage applied to a gate electrode of the driving transistor DT.

A semiconductor layer of the first switching transistor ST1 and/or the driving transistor DT may include semiconductor oxide such as indium-gallium-zinc-oxide (IGZO), but is not limited thereto.

The light emitting device OLED may emit light corresponding to the driving current. The light emitting device OLED may emit light corresponding to one color of red (R), green (G), blue (B), and white.

The light emitting device OLED may include the anode electrode, an emission layer disposed on the anode electrode, and a cathode electrode supplying a common voltage (such as a low-level driving voltage EVSS). The emission layer may be implemented to emit light of the same color for each pixel, like white light, or may be implemented to emit lights of different colors for each subpixel SP, like red (R) light, green (G) light, or blue (B) light.

The light emitting device OLED may be a diode of a top emission type, or may be a diode of a bottom emission type.

In part (a) of FIG. 2, a case where the driving transistor DT is directly connected to the light emitting device OLED is illustrated for example, but the present disclosure is not limited thereto and as illustrated in part (b) of FIG. 2, the driving transistor DT may be connected to the light emitting device OLED through a second switching transistor ST2.

In detail, as in part (b) of FIG. 2, the second switching transistor ST2 may be disposed between the driving transistor DT and the light emitting device OLED, a first electrode of the second switching transistor ST2 may be connected to the driving transistor DT, and a second electrode of the second switching transistor ST2 may be electrically connected to the light emitting device OLED. In response to an emission signal EM applied to the gate electrode of the second switching transistor ST2, the second switching transistor ST2 may control the on/off of the driving current applied from the driving transistor DT to the light emitting device OLED.

Moreover, although not shown in parts (a) and (b) of FIG. 2, a compensation circuit (not shown) for compensating for a threshold voltage of the driving transistor DT may be further included in the subpixel SP. The compensation circuit may include at least one transistor connected to the driving transistor DT and may be provided in the subpixel SP.

Based on a configuration type, the compensation circuit may have a 3T1C structure where three transistors and one capacitor Cst are included in the subpixel SP, or a 4T2C structure where four transistors and two capacitors Cst are included in the subpixel SP, or various structures such as 5T2C, 6T1C, 6T2C, 7T1C, and 7T2C.

Furthermore, in each subpixel SP illustrated in FIGS. 1 and 2, the first and second switching transistors may require a relatively short channel compared to the driving transistor, based on a narrow layout area.

When a transistor has a relatively short channel, a roll-off phenomenon where a threshold voltage Vth of the transistor has a negative (−) value may occur. In this case, driving of the display panel 10 may be unstable.

An embodiment of the present disclosure may improve an interlayer structure of an insulation layer disposed on each transistor to maximize a channel length of a switching transistor, and thus, may enhance the reliability of a transistor and the display panel 10 and may reduce power consumption.

Moreover, each subpixel SP may be changed in characteristic of a driving transistor, based on a color of light emitted therefrom.

For example, comparing with red (R) or blue (B), green (G) may relatively largely affect a color of light emitted from a unit pixel. Based thereon, in an embodiment of the present disclosure, an interlayer structure of an insulation layer disposed under a driving transistor of a green (G) subpixel SP may differ from an interlayer structure of an insulation layer disposed under a driving transistor of a red (R) or blue (B) subpixel SP, so as to increase a sub-threshold swing (S-factor) of the driving transistor included in the green (G) subpixel SP.

Moreover, in each subpixel SP, the driving transistor of the blue (B) subpixel SP may require a relatively high on current (Ion) current characteristic compared to the driving transistor of the green (G) subpixel SP. Based thereon, in an embodiment of the present disclosure, an interlayer structure of an insulation layer disposed on the driving transistor of the blue (B) subpixel SP may differ from an interlayer structure of an insulation layer disposed on the driving transistor of the green (G) subpixel SP.

Hereinafter, as described above, a detailed embodiment where an interlayer structure of an insulation layer is improved will be described for improving a characteristic of a switching transistor and a characteristic of a driving transistor.

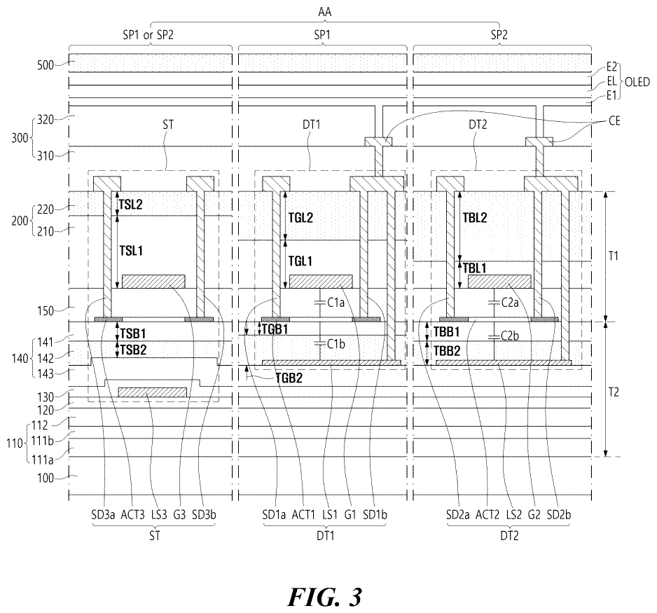

FIG. 3 is a diagram for describing an embodiment of an interlayer structure of a display panel including a switching transistor and a driving transistor according to a first embodiment of the present disclosure.

An interlayer structure of a display panel 10 according to an embodiment of the present disclosure illustrated in FIG. 3 represents an interlayer structure of each of first and second subpixels SP1 and SP2 emitting lights of different colors. As in FIG. 2 (a), FIG. 3 illustrates a case where driving transistors DT1 and DT2 included in first and second subpixels SP1 and SP2 are electrically connected to a light emitting device OLED, but the present disclosure is not limited thereto. For example, as in FIG. 2 (b), the driving transistors DT1 and DT2 may be electrically connected to the light emitting device OLED through a switching transistor ST.

In FIG. 3, the switching transistor ST included in the first and second subpixels SP1 and SP2 in common is illustrated as one. The switching transistor ST illustrated in FIG. 3 may be one of the first and second switching transistors ST1 and ST2 of FIG. 2. In FIG. 3, a case where the switching transistor ST is the ST1 of FIG. 2 is illustrated for example, but the present disclosure is not limited thereto and the switching transistor ST of FIG. 3 may be the ST2 of FIG. 2.

The first and second subpixels SP1 and SP2 illustrated in FIG. 3 may be a subpixel SP emitting lights of different colors. For example, the first subpixel SP1 may be a subpixel SP emitting green (G) light, and the second subpixel SP2 may be a subpixel SP emitting blue (B) or red (R) light.

Therefore, in FIG. 3, a first driving transistor DT1 may be a transistor which controls a magnitude of a driving current supplied to a green (G) light emitting device OLED, and a second driving transistor DT2 may be a transistor which controls a magnitude of a driving current supplied to a blue (B) or red (R) light emitting device OLED.

In FIG. 3, because an influence of green (G) on a color of light emitted from a unit pixel is relatively greater than blue (B) or red (R), a case is illustrated where the first driving transistor DT1 is a transistor of the first subpixel SP1 emitting green (G) light, and the second driving transistor DT2 is a transistor of the second subpixel SP2 emitting blue (B) or red (R) light, but the present disclosure is not limited thereto.

The display panel 10 according to an embodiment of the present disclosure illustrated in FIG. 3 may include a substrate 100, a substrate buffer layer 110, a first gate insulation layer 120, a lower interlayer insulation layer 130, a device buffer layer 140, a second gate insulation layer 150, an upper interlayer insulation layer 200, a planarization layer 300, a light emitting device OLED, an encapsulation layer 500, a switching transistor ST, a first driving transistor DT1, and a second driving transistor DT2.

The substrate 100 may include a plastic material having flexibility and may have a flexible characteristic, and moreover, may include a glass material of a thin thickness having flexibility. The substrate 100 may be disposed in an active area AA and a non-active area NA of the display panel 10.

The substrate 100 may have a multi-layer structure including an insulating material. For example, the substrate 100 may include an insulating material and a polymer material such as polyimide (PI).

The substrate buffer layer 110 may be disposed in the active area AA and the non-active area NA of the substrate 100. The substrate buffer layer 110 may protect structures on the substrate 100 vulnerable to the penetration of external water and may planarize a surface of the substrate 100.

The substrate buffer layer 110 may include an insulating material, and for example, may include an inorganic insulating material such as silicone oxide (SiOx) and silicone nitride (SiNx) and may include a multi-layer structure including the same material or different materials.

For example, the substrate buffer layer 110 may include a multi buffer layer 111a and 111b and an active buffer layer 112, which include different insulating materials and are stacked.

For example, the multi buffer layer 111a and 111b may include a first multi buffer layer 111a and a second multi buffer layer 111b. The first multi buffer layer 111a may be disposed on the substrate 100 and may include silicone oxide SiOx, and the second multi buffer layer 111b may be disposed on the first multi buffer layer 111a and may include silicone nitride SiNx. The active buffer layer 112 may be disposed on the second multi buffer layer 111b and may include SiOx.

The first gate insulation layer 120 may be disposed on the active buffer layer 112 of the substrate buffer layer 110. The first gate insulation layer 120 may include at least one inorganic insulating material among SiOx, SiNx, and silicone oxynitride (SiOxNy). The first gate insulation layer 120 may include SiOx.

The lower interlayer insulation layer 130 may be disposed on the first gate insulation layer 120 and may fully cover the active area AA of the substrate 100. The lower interlayer insulation layer 130 may include an inorganic insulating material, and for example, may include at least one inorganic layer among SiOx, SiNx, and SiOxNy. For example, the lower interlayer insulation layer 130 may include SiNx.

The device buffer layer 140 may be disposed on the lower interlayer insulation layer 130. The device buffer layer 140 may include an inorganic insulating material. For example, the device buffer layer 140 may include an inorganic insulating material such as SiOx or SiNx.

The device buffer layer 140 may have a multi-layer structure including different materials. For example, the device buffer layer 140 may include a first device buffer layer 141, a second device buffer layer 142, and a third device buffer layer 143.

The third device buffer layer 143 may be disposed on the lower interlayer insulation layer 130, and for example, may include SiOx. The second device buffer layer 142 may be disposed on the third device buffer layer 143, and for example, may include SiNx. The first device buffer layer 141 may be disposed on the second device buffer layer 142, and for example, may include SiOx.

The first device buffer layer 141 may be deposited on the second device buffer layer 142, and then, a chemical mechanical polishing (CMP) process may be performed on an upper surface of the first device buffer layer 141 so as to planarize a surface.

Based on the CMP process on the first device buffer layer 141, a step height on the first device buffer layer 141 may be removed, and the first device buffer layer 141 may have a thickness which differs for each position. For example, a thickness of the first device buffer layer 141 disposed under the first driving transistor DT1 may differ from that of the first device buffer layer 141 disposed under the switching transistor ST or the second driving transistor DT2.

Dielectric constants of the first and second device buffer layers 141 and 142 may differ. Due to a dielectric constant difference between the first and second device buffer layers 141 and 142, capacitances formed by the first and second device buffer layers 141 and 142 may differ based on thicknesses of the first and second device buffer layers 141 and 142.

The present disclosure may adjust the capacitances formed by the first and second device buffer layers 141 and 142 by using a thickness difference between the first and second device buffer layers 141 and 142, and thus, may adjust an S-factor to be suitable for a desired characteristic of each of the first and second driving transistors DT1 and DT2 which supply a driving current to the light emitting devices OLED emitting lights of different colors. For example, thicknesses of the first and second device buffer layers 141 and 142 may differ, and thus, may increase an S-factor of the first driving transistor DT1 which is targeted. This may be described in detail after the other layer of the display panel 10 is described.

Herein, an example of a method of differently forming a thickness of a portion of the second device buffer layer 142 may be described as follows. First, the second device buffer layer 142 may be deposited on the third device buffer layer 143 with a uniform thickness, and then, the other portion (for example, a portion of the second device buffer layer 142 disposed under the switching transistor ST and the second driving transistor DT2) except a portion of the second device buffer layer 142 overlapping the first driving transistor DT1 targeted among the first and second driving transistors DT1 and DT2 may be selectively etched by using a mask (not shown), whereby a thickness of the other portion, except a targeted portion, of the second device buffer layer 142 may be formed to be relatively small.

Moreover, an example of a method of differently forming a thickness of the first device buffer layer 141 for each position may be described as follows. The first device buffer layer 141 may be deposited with a uniform thickness on the second device buffer layer 142 formed by differentiating a thickness, and then, an upper surface of the first device buffer layer 141 may be planarized by performing a CMP process on the upper surface of the first device buffer layer 141, whereby a thickness of a portion, overlapping the first driving transistor DT1 targeted, of the first device buffer layer 141 may be formed to be less than that of the other portion.

The second gate insulation layer 150 may be disposed on the first device buffer layer 141, and the second gate insulation layer 150 may include at least one inorganic insulating material among SiOx, SiNx, and SiOxNy. For example, SiOx may include silicone dioxide (SiO₂).

The second gate insulation layer 150 may insulate a gate electrode and a semiconductor layer of the switching transistor ST from each other and may insulate gate electrodes and semiconductor layers of the first and second driving transistors DT1 and DT2 from each other.

The upper interlayer insulation layer 200 may be disposed on the second gate insulation layer 150 and may insulate the gate electrode of the switching transistor ST from the gate electrodes of the first and second driving transistors DT1 and DT2.

The upper interlayer insulation layer 200 may be formed in a multi-layer structure including an insulating material such as SiOx, SiNx, or SiOxNy. For example, the upper interlayer insulation layer 200 may include first and second upper interlayer insulation layers 210 and 220.

The first upper interlayer insulation layer 210 may be disposed on the second gate insulation layer 150 and may include an inorganic insulating material (for example, SiO₂) such as SiOx.

The second upper interlayer insulation layer 220 may be disposed on the first upper interlayer insulation layer 210 and may include an inorganic insulating material which differs from that of the first upper interlayer insulation layer 210. For example, the second upper interlayer insulation layer 220 may include SiNx.

A hydrogen (H) content of the second upper interlayer insulation layer 220 may be higher than a hydrogen content of the first upper interlayer insulation layer 210. The present disclosure may adjust a device characteristic to be suitable for a characteristic of each of the switching transistor ST and the first and second driving transistors DT1 and DT2 by using a hydrogen content difference between the first and second upper interlayer insulation layers 210 and 220.

For example, thicknesses of the first and second upper interlayer insulation layers 210 and 220 may differ for each position, and thus, a channel length of the switching transistor ST may be maximized, and an on current (Ion) characteristic of the first or second driving transistor DT1 or DT2 may be adjusted. This may be described in detail after the other layer of the display panel 10 is described.

Herein, an example of a method of differently forming a thickness of the first device buffer layer 141 for each position may be described as follows. First, the first upper interlayer insulation layer 210 may be deposited with a uniform thickness on the second gate insulation layer 150, and then, a thickness of a targeted portion of the first upper interlayer insulation layer 210 may be selectively etched, whereby a thickness of the first upper interlayer insulation layer 210 may differ for each portion.

A selective etching method, for example, may primarily and selectively etch a portion of the first upper interlayer insulation layer 210 disposed on semiconductor layers of the first and second driving transistors DT1 and DT2 without etching a portion of the first upper interlayer insulation layer 210 disposed on a semiconductor layer of the switching transistor ST, and then, may secondarily and selectively etch a portion of the first upper interlayer insulation layer 210 disposed on the semiconductor layer of the second driving transistor DT2, whereby a thickness of the first upper interlayer insulation layer 210 may differ for each portion.

Moreover, an example of a method of differently forming a thickness of the second upper interlayer insulation layer 220 for each position may be described as follows. The second upper interlayer insulation layer 220 may be deposited with a uniform thickness on the second device buffer layer 142, and then, an upper surface of the second upper interlayer insulation layer 220 may be planarized by performing a CMP process on the upper surface of the second upper interlayer insulation layer 220, whereby a thickness of the second upper interlayer insulation layer 220 may differ for each position.

As described above, after the first and second upper interlayer insulation layers 210 and 220 are formed, an annealing processing based on thermal treatment may be performed. As an annealing process is performed, hydrogen (H) may be doped in the semiconductor layers of the switching transistor ST and the first and second driving transistors DT1 and DT2.

In the present disclosure, as a thickness of each of the first and second upper interlayer insulation layers 210 and 220 may differ for each position, a concentration of doped hydrogen (H) may differ for each semiconductor layer, and thus, a transistor suitable for a desired characteristic of each element may be formed.

The planarization layer 300 may be disposed on the second upper interlayer insulation layer 220 and may include an insulating material. The planarization layer 300 may remove a step height which occurs due to a plurality of transistors disposed in each subpixel SP. An upper surface of the planarization layer 300 may include a flat surface and may include a material having high flowability. For example, the planarization layer 300 may include an organic insulating material.

The planarization layer 300 may include a multi-layer structure where a plurality of layers are stacked, and for example, the planarization layer 300 may a first planarization layer 310 and a second planarization layer 320, which are sequentially stacked, but not limited to it.

The first planarization layer 310 may remove a step height caused by a driving circuit such as the switching transistor ST and the first and second driving transistors DT1 and DT2. An upper surface of each of the first planarization layer 310 and the second planarization layer 320 may include a flat surface. To this end, the first planarization layer 310 and the second planarization layer 320 may include organic insulating materials having the same or different flowability.

A center electrode CE may be disposed between the first planarization layer 310 and the second planarization layer 320. The center electrode CE may include a conductive material, and for example, may include at least one of metals such as aluminum (Al), chrome (Cr), copper (Cu), titanium (Ti), molybdenum (Mo), and tungsten (W).

The center electrode CE may electrically connect the light emitting device OLED and the driving transistors DT1 and DT2 with each other in each subpixel SP. For example, the center electrode CE may pass through the first and second planarization layers 310 and 320 and may electrically connect a first electrode E1 (an anode electrode) of the light emitting device OLED and the driving transistors DT1 and DT2 with each other in each of the first and second subpixels SP1 and SP2.

The light emitting device OLED may be disposed on the planarization layer 300 and may include the first electrode E1, an emission layer EL, and a second electrode E2. The light emitting device OLED may emit light of one color among red (R), green (G), and blue (B). For example, an emission layer disposed in the first subpixel SP1 may emit green (G) light, and an emission layer disposed in the second subpixel SP2 may emit blue (B) or red (R) light.

The first electrode E1, for example, may function as an anode electrode and may include a conductive material. The first electrode E1 may have a high reflectance. For example, the first electrode E1 may include metal such as Al and silver (Ag). The first electrode E1 may have a multi-layer structure. For example, the first electrode E1 may have a structure where a reflective electrode including metal is disposed between transparent electrodes including a transparent conductive material such as indium tin oxide (ITO) or indium zinc oxide (IZO).

The emission layer EL may generate light of luminance corresponding to a voltage difference between the first electrode E1 and the second electrode E2. For example, the emission layer EL may include an emission material layer (EML) including an emission material. The emission material may include an organic material, an inorganic material, or a hybrid material. For example, the emission layer EL may include an emission material layer including an organic material.

The emission layer EL may include at least one of a first emission common layer (not shown) disposed between first electrodes E1 and a second emission common layer (not shown) disposed between second electrodes E2. Each of the first emission common layer (not shown) and the second emission common layer (not shown) may include at least one of a hole injection layer (HIL), a hole transport layer (HTL), an electron transport layer (ETL), and an electron injection layer (EIL).

The second electrode E2, for example, may function as a cathode electrode and may include a conductive material. The second electrode E2 may include a material which differs from that of the first electrode E1. For example, the second electrode E2 may be a transparent electrode including a transparent conductive material such as ITO or IZO. The second electrode E2 may have a transmittance which is higher than that of the first electrode E1. Accordingly, in the display panel 10 according to an embodiment of the present disclosure, light generated by the emission layer EL may be emitted through the second electrode E2.

The encapsulation layer 500 may be disposed on the light emitting device OLED. The encapsulation layer 500 may prevent the damage of light emitting devices OLED caused by external impact and water. The encapsulation layer 500 may have a multi-layer structure. For example, the encapsulation layer 500 may be provided by alternately stacking an encapsulation layer 500 including an inorganic insulating material and an encapsulation layer 500 including an organic insulating material.

Accordingly, in the display panel 10 according to an embodiment of the present disclosure, the damage of the light emitting device OLED caused by external impact and water may be effectively prevented.

The first driving transistor DT1 may control a driving current supplied to the light emitting device OLED of the first subpixel SP1 emitting green (G) light and may include a first gate electrode G1, a first semiconductor layer ACT1, a first source electrode SD1a, a first drain electrode SD1b, and a first metal layer LS1.

The second driving transistor DT2 may control a driving current supplied to the light emitting device OLED of the second subpixel SP2 emitting red (R) or blue (B) light and may include a second gate electrode G2, a second semiconductor layer ACT2, a second source electrode SD2a, a second drain electrode SD2b, and a second metal layer LS2.

The switching transistor ST may be electrically connected to the driving transistor in each of the first subpixel SP1 or the second subpixel SP2 to configure the pixel circuit illustrated in part (a) of FIG. 2 and may include a third gate electrode G3, a third semiconductor layer ACT3, a third source electrode SD3a, a third drain electrode SD3b, and a third metal layer LS3.

The first to third gate electrodes G1 to G3 may be disposed between the second gate insulation layer 150 and the first upper interlayer insulation layer 210. The first to third gate electrodes G1 to G3 may include a conductive material, and for example, may include at least one of metals such as Al, Cr, Cu, Ti, Mo, and W.

The first to third gate electrodes G1 to G3 may respectively control a process of forming channels in the first to third semiconductor layers ACT1 to ACT3 of the transistors D1, D2, and ST, based on voltages applied thereto.

The first to third semiconductor layers ACT1 to ACT3 may be disposed between the second gate insulation layer 150 and the first device buffer layer 141 and may respectively overlap the first to third gate electrodes G1 to G3. The first to third semiconductor layers ACT1 to ACT3 may respectively form channels therein, based on the first to third gate electrodes G1 to G3.

The first to third semiconductor layers ACT1 to ACT3 may include an oxide semiconductor material. The oxide semiconductor material may include, for example, at least one of InZnO (IZO)-based, InGaO (IGO)-based, InSnO (ITO)-based, InGaZnO (IGZO)-based, InGaZnSnO (IGZTO)-based, GaZnSnO (GZTO)-based, GaZnO (GZO)-based, InSnZnO (ITZO)-based, and FeInZnO (FIZO)-based oxide semiconductor materials. The first to third semiconductor layers ACT1 to ACT3 may each be configured as a single layer or a multilayer including at least one oxide semiconductor.

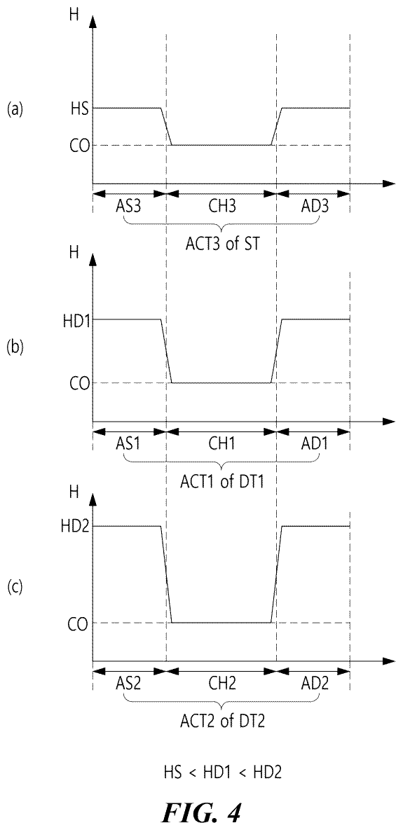

The first to third semiconductor layers ACT1 to ACT3 may include a channel region and conductive regions disposed at both sides with the channel region therebetween. First to third channel regions (CH1 to CH3 of FIG. 4) of the first to third semiconductor layers ACT1 to ACT3 may be disposed to respectively overlap the first to third gate electrodes G1 to G3, and a conductive region may be disposed in regions, which do not overlap the first to third gate electrodes G1 to G3, of the first to third semiconductor layers ACT1 to ACT3.

One of the conductive regions in the first to third semiconductor layers ACT1 to ACT3 may be first to third source regions (AS1 to AS3 of FIG. 4), and the other one conductive region may be first to third drain regions (AD1 to AD3 of FIG. 4). Each of the first to third semiconductor layers ACT1 to ACT3 may form a conductive region by using hydrogen as a dopant. Accordingly, the conductive region in each of the first to third semiconductor layers ACT1 to ACT3 may be doped with hydrogen (H) at a high concentration, and the channel region may be doped with hydrogen (H) at a concentration which is lower than that of the conductive region.

In the present disclosure, a concentration of hydrogens doped in the conductive regions of the first to third semiconductor layers ACT1 to ACT3 may differ. This will be described below with reference to FIG. 4.

Each of the first to third source electrodes SD1a to SD3a and the first to third drain electrodes SD1b to SD3b may be disposed between the second upper interlayer insulation layer 220 and the first planarization layer 310 and may contact a conductive region of each of the first to third semiconductor layers ACT1 to ACT3. For example, each of the first to third source electrodes SD1a to SD3a and the first to third drain electrodes SD1b to SD3b may pass through the second upper interlayer insulation layer 220 and the second gate insulation layer 150 and may contact the conductive region of each of the first to third semiconductor layers ACT1 to ACT3.

The first to third source electrodes SD1a to SD3a and the first to third drain electrodes SD1b to SD3b may include the same material, and for example, may include at least one of metals such as Al, Cr, Cu, Ti, Mo, and W.

The first and second metal layers LS1 and LS2 may be disposed between the second device buffer layer 142 and the third device buffer layer 143, the first metal layer LS1 may overlap the first semiconductor layer ACT1, and the second metal layer LS2 may overlap the second semiconductor layer ACT2. The first and second metal layers LS1 and LS2 may block external light incident on the first and second semiconductor layers ACT1 and ACT2.

The first and second metal layers LS1 and LS2 may pass through the upper interlayer insulation layer 200, the second gate insulation layer 150, and the first and second device buffer layers 141 and 142 and may respectively contact the first and second drain electrodes SD1b and SD2b. The first and second metal layers LS1 and LS2 may include the same conductive material.

The third metal layer LS3 may be disposed between the first gate insulation layer 120 and the lower interlayer insulation layer 130 and may overlap the third semiconductor layer ACT3. The third metal layer LS3 may block external light incident on the third semiconductor layer ACT3, and although not shown, may be electrically connected to the third gate electrode G3. Accordingly, the third metal layer LS3 may function as a bottom gate electrode. The third metal layer LS3 may include a conductive material which differs from that of each of the first and second metal layers LS1 and LS2.

In such an interlayer structure of the display panel 10, the present disclosure may form the conductive regions of the first to third semiconductor layers ACT1 to ACT3 through hydrogen doping and may allow a content and a movement distance of hydrogen included in layers disposed on or under the first to third semiconductor layers ACT1 to ACT3 to differ, and thus, may secure device performance based on a desired characteristic of each transistor.

Hereinafter, for convenience of description, an upper interlayer insulation layer or a device buffer layer disposed to overlap on or under a semiconductor layer of a specific transistor may be referred to as ‘an upper interlayer insulation layer or a device buffer layer of a specific transistor.’

In the present disclosure, a thickness TSL1 of the first upper interlayer insulation layer 210 disposed on the semiconductor layer of the switching transistor ST may differ from thicknesses TGL1 and TBL1 of the first upper interlayer insulation layer 210 disposed on the semiconductor layers of the driving transistors DT1 and DT2.

The thickness TSL1 of the first upper interlayer insulation layer 210 of the switching transistor ST may be greater than the thicknesses TGL1 and TBL1 of the first upper interlayer insulation layers 210 of the driving transistors DT1 and DT2.

Therefore, in a process of depositing the second upper interlayer insulation layer 220, a distance by which hydrogen moves from the second upper interlayer insulation layer 220 of the switching transistor ST to the third semiconductor layer ACT3 may be relatively longer than a distance by which hydrogen moves from the second upper interlayer insulation layers 220 of the driving transistors DT1 and DT2 to the first and second semiconductor layers ACT1 and ACT2, and a concentration of hydrogen doped in the conductive region of the third semiconductor layer ACT3 of the switching transistor ST may be less than a concentration of hydrogen doped in the conductive regions of the first and second semiconductor layers ACT1 and ACT2.

Accordingly, the amount of hydrogen diffused to an inner portion of the third gate electrode G3 in the third semiconductor layer ACT3 of the switching transistor ST may be relatively small, and thus, a channel region formed in the third semiconductor layer ACT3 may be maximized.

Moreover, in the present disclosure, a thickness TSL2 of the second upper interlayer insulation layer 220 of the switching transistor ST may differ from thicknesses TGL2 and TBL2 of the second upper interlayer insulation layers 220 of the first and second driving transistors DT1 and DT2. For example, the thickness TSL2 of the second upper interlayer insulation layer 220 of the switching transistor ST may be less than the thicknesses TGL2 and TBL2 of the second upper interlayer insulation layers 220 of the first and second driving transistors DT1 and DT2.

Moreover, in the switching transistor ST, the thickness TSL1 of the first upper interlayer insulation layer 210 may be greater than the thickness TSL2 of the second upper interlayer insulation layers 220.

As described above, a hydrogen (H) content of the second upper interlayer insulation layer 220 may be greater than a hydrogen content of the first upper interlayer insulation layer 210. After the second upper interlayer insulation layer 220 is deposited on the first upper interlayer insulation layer 210, a CMP process may be performed on the second upper interlayer insulation layer 220, and then, hydrogen may be doped through an annealing process. That is, hydrogen included in the second upper interlayer insulation layer 220 may be doped in the first to third semiconductor layers ACT1 to ACT3 in the middle of the annealing process.

The second upper interlayer insulation layer 220 of the switching transistor ST may have the thickness TSL2 which is relatively small, and when performing the annealing process, the amount of hydrogen doped in the third semiconductor layer ACT3 of the switching transistor ST may be less than the amount of hydrogen doped in the first and second semiconductor layers ACT1 and ACT2 of the first and second driving transistors DT1 and DT2.

Therefore, the amount of hydrogen diffused to the third semiconductor layer ACT3 of the switching transistor ST may be relatively small, and the diffusion of hydrogen to a lower portion of the third gate electrode G3 in the third semiconductor layer ACT3 may be minimized.

Accordingly, a reduction in the channel region CH3 of the third semiconductor layer ACT3 may be minimized, and a channel length of the switching transistor ST having a relatively short channel may be maximized.

The first upper interlayer insulation layer 210 and the second upper interlayer insulation layer 220 may include different materials, and for example, the first upper interlayer insulation layer 210 may include SiOx, and the second upper interlayer insulation layer 220 may include SiNx.

Moreover, the thickness TGL1 of the first upper interlayer insulation layer 210 of the first driving transistor DT1 may differ from the thickness TBL1 of the first upper interlayer insulation layer 210 of the second driving transistor DT2, and the thickness TGL2 of the second upper interlayer insulation layer 220 of the first driving transistor DT1 may differ from the thickness TBL2 of the second upper interlayer insulation layer 220 of the second driving transistor DT2.

For example, the thickness TBL1 of the first upper interlayer insulation layer 210 of the second driving transistor DT2 may be less than the thickness TGL1 of the first upper interlayer insulation layer 210 of the first driving transistor DT1, and the thickness TBL2 of the second upper interlayer insulation layer 220 of the second driving transistor DT2 may be greater than the thickness TGL2 of the second upper interlayer insulation layer 220 of the first driving transistor DT1.

Moreover, in the second driving transistor DT2, the thickness TBL2 of the second upper interlayer insulation layer 220 may be greater than the thickness TBL1 of the first upper interlayer insulation layer 210.

In a case where the second driving transistor DT2 of the second subpixel SP2 controls a driving current of the light emitting device OLED emitting blue (B) light, the second driving transistor DT2 may need an on current (Ion) characteristic which is higher than that of the light emitting device OLED emitting green (G) light.

Based thereon, in the present disclosure, in the second driving transistor DT2, the thickness TBL2 of the second upper interlayer insulation layer 220 may be relatively large, and the thickness TBL1 of the first upper interlayer insulation layer 210 may be relatively small, and thus, a relatively high amount of hydrogen may be doped in the second semiconductor layer ACT2, thereby responding to a relatively high on current (Ion) characteristic of the second driving transistor DT2.

In the present disclosure, as described above, based on thicknesses of the first and second upper interlayer insulation layers 210 and 220, a CMP process may be performed on the second upper interlayer insulation layer 220, and thus, in each of the switching transistor ST and the first and second driving transistors DT1 and DT2, the second upper interlayer insulation layers 220 may have the same height level (or in other words, ‘lie in a common plane,’ or ‘have top surfaces at a uniform height,’ or ‘have top surfaces that are coplanar’) and may each include a planarized upper surface.

Therefore, in each of regions where the switching transistor ST and the first and second driving transistors DT1 and DT2 are disposed, a thickness T1 up to the upper surface of the second upper interlayer insulation layers 220 from the upper surface of the first device buffer layer 141 may be uniform and equal.

The first and second device buffer layers 141 and 142 may have different dielectric constants and may include different inorganic insulating materials. For example, the first device buffer layer 141 may include SiOx, and the second device buffer layer 142 may include SiNx.

In the present disclosure, thicknesses of the first and second device buffer layers 141 and 142 may differ to be suitable for a desired characteristic of each of the first and second driving transistors DT1 and DT2, based on a dielectric constant characteristic of each of the first and second device buffer layers 141 and 142.

In detail, in the present disclosure, in order to more increase an S-factor of the first driving transistor DT1, a thickness TGB1 of the first device buffer layer 141 of the first driving transistor DT1 may differ from a thickness TBB1 of the first device buffer layer 141 of the second driving transistor DT2, and a thickness TGB2 of the second device buffer layer 142 of the first driving transistor DT1 may differ from a thickness TBB2 of the second device buffer layer 142 of the second driving transistor DT2.

For example, the thickness TGB1 of the first device buffer layer 141 of the first driving transistor DT1 may be less than the thickness TBB1 of the first device buffer layer 141 of the second driving transistor DT2, and the thickness TGB2 of the second device buffer layer 142 of the first driving transistor DT1 may be greater than the thickness TBB2 of the second device buffer layer 142 of the second driving transistor DT2.

Moreover, under the first driving transistor DT1, the thickness TGB1 of the first device buffer layer 141 may be less than the thickness TGB2 of the second device buffer layer 142, and the thicknesses TBB1 and TBB2 of the first and second device buffer layers 141 and 142 disposed under the second driving transistor DT2 may be equal to the thicknesses TSB1 and TSB2 of the first and second device buffer layers 141 and 142 disposed under the switching transistor ST.

In the present disclosure, as described above, under the first driving transistor DT1, the thickness TGB1 of the first device buffer layer 141 may be relatively small, and the thickness TGB2 of the second device buffer layer 142 may be relatively large, and thus, an S-factor of the first driving transistor DT1 which relatively largely affects a color of a unit pixel may more increase, and the gray expression of a color of light emitted from a unit pixel may be more stably controlled.

The first and second device buffer layers 141 and 142 may be respectively disposed between the first and second semiconductor layers ACT1 and ACT2 and the first and second metal layers LS1 and LS2, and thus, a capacitor may be formed.

The first and second device buffer layers 141 and 142 may include different materials, and thus, may differ in dielectric constant, and even when distances between the first and second semiconductor layers ACT1 and ACT2 and the first and second metal layers LS1 and LS2 are equal to each other, capacitances C1b and C2b may be differently formed based on thicknesses of the first and second device buffer layers 141 and 142.

The first device buffer layer 141 including SiOx may increase in capacitance of a capacitor as a thickness thereof decreases, and moreover, may decrease in capacitance of the capacitor as the thickness thereof increases.

The second device buffer layer 142 including SiNx may increase in capacitance of a capacitor as a thickness thereof increases, and moreover, may decrease in capacitance of the capacitor as the thickness thereof decreases.

Therefore, buffer capacitances C1b and C2b of the device buffer layer 140 including the first and second device buffer layers 141 and 142 may increase as a thickness of the first device buffer layer 141 decreases and may increase as a thickness of the second device buffer layer 142 increases.

Moreover, an S-factor of each of the first and second driving transistors DT1 and DT2 may be determined based on a ratio of first and second gate capacitances C1a and C2a between each gate electrode and each semiconductor layer and first and second buffer capacitances C1b and C2b between each semiconductor layer and each metal layer.

In detail, the S-factor of each of the first and second driving transistors DT1 and DT2 may increase as the first and second buffer capacitances C1b and C2b increase, with respect to the first and second gate capacitances C1a and C2a.

The present disclosure may adjust a thickness of each of the first and second device buffer layers 141 and 142 by using a relationship between an S-factor, a gate capacitor, and a buffer capacitor and may thus adjust an S-factor of a targeted transistor in the first and second driving transistors DT1 and DT2.

In FIG. 3, with respect to targeting the first driving transistor DT1, an example is illustrated where the thickness TGB1 of the first device buffer layer 141 of the first driving transistor DT1 is relatively small, and the thickness TGB2 of the second device buffer layer 142 is relatively large, and thus, a capacitance C1b of a first buffer capacitor is relatively large, and an S-factor of the first driving transistor DT1 increases.

Moreover, an example is illustrated where thicknesses TBB1 and TBB2 of first and second device buffer layers 141 and 142 of the second driving transistor DT2 which is not targeted are equal to thicknesses TSB1 and TSB2 of first and second device buffer layers 141 and 142 of the switching transistor ST.

In the present disclosure, as described above, based on thicknesses of the first and second device buffer layers 141 and 142, a CMP process may be performed on the first device buffer layer 141, and thus, the first device buffer layer 141 disposed under the switching transistor ST and the first device buffer layer 141 disposed under the first and second driving transistors DT1 and DT2 may each include a planarized upper surface, and the semiconductor layer of the switching transistor ST and the semiconductor layers included in the first and second driving transistors DT1 and DT2 may may be disposed on the first device buffer layer 141 having the same height level.

Therefore, in each of regions where the switching transistor ST and the first and second driving transistors DT1 and DT2 are disposed, a thickness T2 up to the upper surface of the first device buffer layer 141 from the upper surface of the substrate 100 may be uniform and equal.

As described above, in the first embodiment of the present disclosure, in the switching transistor ST requiring a relatively short channel length in each subpixel SP, a thickness TSL1 of the first upper interlayer insulation layer 210 may be set to be relatively large, and a thickness TSL2 of the second upper interlayer insulation layer 220 may be set to be relatively small, and thus, a concentration of hydrogen doped in the semiconductor layer of the switching transistor ST may be reduced, thereby maximizing a channel of the switching transistor ST and allowing a threshold voltage (Vth) of the switching transistor ST to be positive-shifted (+shifted).

Moreover, in the first embodiment of the present disclosure, in the first driving transistor DT1 requiring relatively stable gray expression in each subpixel SP, a thickness TGB1 of the first device buffer layer 141 may be set to be relatively small, and a thickness TGB2 of the second device buffer layer 142 may be set to be relatively large, and thus, an S-factor of the first driving transistor DT1 may increase, thereby more stabilizing the gray expression of a unit pixel.

Moreover, in the first embodiment of the present disclosure, in the second driving transistor DT2 requiring a relatively high on current (Ion) characteristic in each subpixel SP, a thickness TBL1 of the first upper interlayer insulation layer 210 may be set to be relatively small, and a thickness TBL2 of the second upper interlayer insulation layer 220 may be set to be relatively large, and thus, a concentration of hydrogen doped in the semiconductor layer of the first and second driving transistors DT1 and DT2 may increase, thereby responding to a high on current (Ion) characteristic of the semiconductor layer of the second driving transistor DT2 and decreasing power consumption.

Hereinafter, the hydrogen concentration, threshold voltage, and S-factor of the semiconductor layer of each of the switching transistor ST and the first and second driving transistors DT1 and DT2 will be described.

FIG. 4 is a diagram for describing a hydrogen concentration in the semiconductor layer of each of the switching transistor and the first and second driving transistors illustrated in FIG. 3.

Part (a) of FIG. 4 is a graph of a concentration of hydrogen (H) doped in a third semiconductor layer ACT3 of a switching transistor ST, part (b) of FIG. 4 is a graph of a concentration of hydrogen (H) doped in a first semiconductor layer ACT1 of a first driving transistor DT1, and part (c) of FIG. 4 is a graph of a concentration of hydrogen (H) doped in a second semiconductor layer ACT2 of a second driving transistor DT2.

As illustrated in part (a) of FIG. 4, in the third semiconductor layer ACT3 of the switching transistor ST, the amount of hydrogen doped from the second upper interlayer insulation layer 220 may be relatively small, and thus, a hydrogen concentration HS doped in a third source region AS3 and a third drain region AD3 may be less than a hydrogen concentration HD1 of the first driving transistor DT1 of part (b) of FIG. 4 and a hydrogen concentration HD2 of the second driving transistor DT2 of part (c) of FIG. 4.

Moreover, as illustrated in part (c) of FIG. 4, in the second semiconductor layer ACT2 of the second driving transistor DT2, the amount of hydrogen doped from the second upper interlayer insulation layer 220 may be relatively large, and thus, a hydrogen concentration HD2 doped in a second source region AS2 and a second drain region AD2 may be higher than the hydrogen concentration HD1 of the first driving transistor DT1 of part (b) of FIG. 4.

Moreover, as illustrated in part (b) of FIG. 4, in the first semiconductor layer ACT1 of the second driving transistor DT1, the amount of hydrogen doped from the second upper interlayer insulation layer 220 may have a middle value, and thus, a hydrogen concentration HD1 doped in a first source region AS1 and a first drain region AD1 may have a middle value between the hydrogen concentration HD1 of the first driving transistor DT1 of part (a) of FIG. 4 and the hydrogen concentration HS of the second driving transistor DT2 of part (c) of FIG. 4.

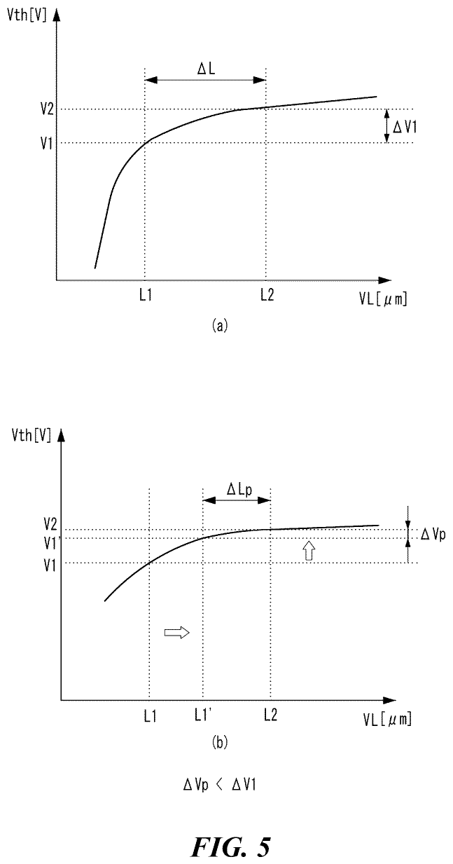

FIG. 5 is a diagram for describing a channel valid length difference and a threshold voltage (Vth) difference between a switching transistor and first and second driving transistors improved according to a second embodiment of the present disclosure.

Part (a) of FIG. 5 illustrates a channel valid length difference and a threshold voltage (Vth) difference between a switching transistor ST and a driving transistor DT in a case where thicknesses of first and second upper interlayer insulation layers 210 and 220 are equal to each other, in a portion where the switching transistor ST and the driving transistor DT are disposed in each subpixel.

In a case where thicknesses of first and second upper interlayer insulation layers 210 and 220 of the switching transistor ST and thicknesses of first and second upper interlayer insulation layers 210 and 220 of the driving transistor DT are equal to each other, as in part (a) of FIG. 5, a valid length of a channel formed in a semiconductor layer of the switching transistor ST may have a first length L1, and a valid length of a channel formed in a semiconductor layer of the driving transistor DT may have a second length L2.

In this case, a threshold voltage Vth of the switching transistor ST may have a first voltage V1, and a threshold voltage Vth of the driving transistor DT may have a second voltage V2 which is higher than the first voltage V1.

Therefore, in a case where the thicknesses of the first and second upper interlayer insulation layers 210 and 220 of the switching transistor ST and the thicknesses of the first and second upper interlayer insulation layers 210 and 220 of the driving transistor DT are equal to each other, as in part (a) of FIG. 5, a valid length difference of a channel between the switching transistor ST and the driving transistor DT may be ΔL, and a difference of a threshold voltage Vth therebetween may be ΔV1.

On the other hand, as described above, in a case where the thicknesses of the first and second upper interlayer insulation layers 210 and 220 of the switching transistor ST and the thicknesses of the first and second upper interlayer insulation layers 210 and 220 of the driving transistor DT differ for each position, as in part (b) of FIG. 5, the present disclosure may increase a channel valid length of the switching transistor ST from L1 to L1′ and may also increase the threshold voltage Vth from V1 to V1′.

That is, as described above with reference to FIG. 3, in the present disclosure, a thickness TSL2 of the second upper interlayer insulation layer 220, where a content of hydrogen is high, of the switching transistor ST may be relatively less than TGL2 and TBL2, and a thickness TSL1 of the first upper interlayer insulation layer 210, which is lower in hydrogen content than the second upper interlayer insulation layer 220, of the switching transistor ST may be relatively greater than TGL1 and TBL1, and thus, a movement distance of hydrogen moving up to the third semiconductor layer ACT3 of the switching transistor ST from the second upper interlayer insulation layer 220 may increase, and a concentration of hydrogen may be relatively reduced.

Therefore, the amount of hydrogen doped in the third semiconductor layer ACT3 of the switching transistor ST may be less than the amount of hydrogen doped in the first and second semiconductor layers ACT1 and ACT3 of the first and second driving transistors DT1 and DT2.

Accordingly, the diffusion of hydrogen doped in the third semiconductor layer ACT3 to a lower portion of the third gate electrode G3 may be minimized, and a reduction in the channel region CH3 of the third semiconductor layer ACT3 may be minimized.

As a result, comparing with part (a) of FIG. 5, as illustrated in part (b) of FIG. 5, the present disclosure may form the channel region CH3 of the switching transistor ST by L1′ which is greater than L1 and may increase the threshold voltage Vth of the switching transistor ST from V1 to V1′.

Therefore, according to the present disclosure, in portions where the switching transistor ST and the driving transistor DT are disposed, the thicknesses of the first and second upper interlayer insulation layers 210 and 220 may differ for each position, and thus, a valid length difference of a channel between the switching transistor ST and the driving transistor DT may decrease from ΔL to ΔLp, and a difference of a threshold voltage Vth therebetween may decrease from ΔV1 to ΔVp.

As in part (a) of FIG. 5, in a state where a threshold voltage difference between the switching transistor ST and the first and second driving transistors DT1 and DT2 has a difference of ΔV1, when the threshold voltage Vth of each of the first and second driving transistors DT1 and DT2 is positive-shifted, an issue of reliability of a pixel driving circuit may occur.

Furthermore, even when the threshold voltage Vth of each of the first and second driving transistors DT1 and DT2 is negative-shifted by adjusting a driving signal so as to improve reliability, the threshold voltage Vth of the switching transistor ST may be shifted together, causing a problem.

However, according to the present disclosure, the thicknesses of the first and second upper interlayer insulation layers 210 and 220 of the switching transistor ST may differ from the thicknesses of the first and second upper interlayer insulation layers 210 and 220 of the first and second driving transistors DT1 and DT2, and thus, a difference ΔLp of the valid channel length may decrease. Accordingly, the present disclosure may more stably secure the reliability of a pixel driving circuit.

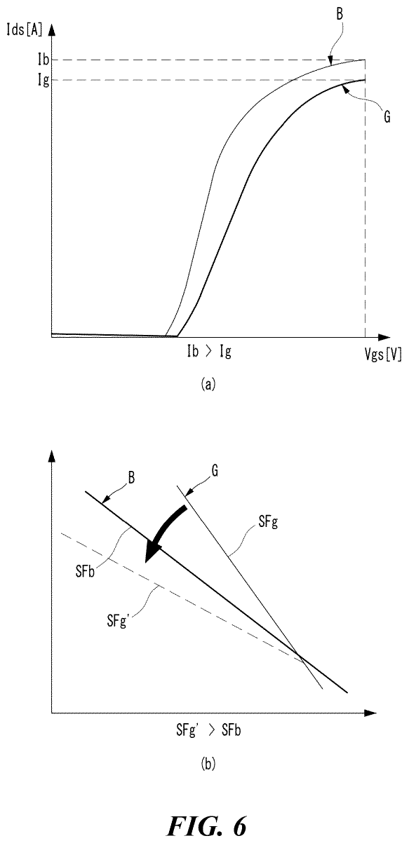

FIG. 6 is a diagram for describing an S-factor and a characteristic graph of a driving transistor improved according to a first embodiment of the present disclosure.

Part (a) of FIG. 6 is a characteristic graph of a general driving transistor to which an embodiment of the present disclosure is not applied, and part (b) of FIG. 6 is a diagram illustrating an S-factor of a driving transistor with respect to the characteristic graph shown in part (a) of FIG. 6.

As in part (a) of FIG. 6, the characteristic graph of the general driving transistor represents a relationship between a driving current Ids and a gate-source voltage Vgs of a driving transistor, and in part (a) of FIG. 6, B represents a characteristic graph of a driving transistor of a blue (B) subpixel, and G represents a characteristic graph of a driving transistor of a green (G) subpixel.

In part (a) of FIG. 6, in a state where a Vgs voltage has a maximum value, a value of the driving current Ids may be referred to as an on current Ion. In a general case, an on current (Ion) value of the driving transistor of the blue (B) subpixel may be Ib and may have a value which is greater than Ig which is an on current (Ion) value of the driving transistor of the green (G) subpixel.

The on current (Ion) value of the driving transistor of the blue (B) subpixel may be a value associated with a light emitting device OLED emitting blue (B) light and may have a characteristic needed for the driving transistor of the blue (B) subpixel.

According to the present disclosure, based on a characteristic needed for the driving transistor of the blue (B) subpixel, in a second subpixel SP2 emitting blue (B) light, the thicknesses of the first and second upper interlayer insulation layers 210 and 220 of the second driving transistor DT2 may be adjusted, and thus, a concentration of hydrogen doped in the second semiconductor layer ACT2 of the second driving transistor DT2 may be relatively large, thereby decreasing the power consumption of the second driving transistor DT2.

In detail, as described above with reference to FIG. 3, in the second driving transistor DT2, the thickness TBL2 of the second upper interlayer insulation layer 220 where a content of hydrogen is high may be relatively large, and the thickness TBL1 of the first upper interlayer insulation layer 210 where a content of hydrogen is low may be relatively small, and thus, a relatively high amount of hydrogen may be doped in the second semiconductor layer ACT2. Accordingly, a relatively high amount of hydrogen may be doped in the second semiconductor layer ACT2 of the second driving transistor DT2 requiring a relatively high on current (Ion) characteristic, and thus, a carrier concentration of the second semiconductor layer ACT2 may increase.

Accordingly, the present disclosure may implement a high on current (Ion) characteristic of the second driving transistor DT2 with a relatively low consumption power.

Moreover, the S-factor of the driving transistor illustrated in part (b) of FIG. 6 may be expressed as an inverse number on a slope by where a graph increases near a threshold voltage Vth in the characteristic graph of the driving transistor.

In part (a) of FIG. 6, in the driving transistor of the blue (B) subpixel, a slope of a graph may be relatively large near a threshold voltage Vth thereof, and thus, as in part (b) of FIG. 6, an S-factor SFb of the driving transistor of the blue (B) subpixel may have a relatively large value, and a slope of a graph may be relatively gentle.

Moreover, in part (a) of FIG. 6, in the driving transistor of the green (G) subpixel, a slope of a graph may be relatively gentle near a threshold voltage Vth thereof, and thus, as in part (b) of FIG. 6, an S-factor SFg of the driving transistor of the green (G) subpixel may have a relatively small value, and a slope of a graph may be relatively large.

As the S-factor SFb of the driving transistor has a relatively large value, a slope of a graph may be relatively gentle, and gray expression may be more stabilized.

For example, when the thicknesses of the first device buffer layers 141 of the first and second driving transistors DT1 and DT2 are equal to each other, and the thicknesses of the second device buffer layers 142 of the first and second driving transistors DT1 and DT2 are equal to each other, as in part (b) of FIG. 6, an S-factor SFg of the first driving transistor DT1 of the green (G) subpixel may have a value which is relatively less than that of an S-factor SFb of the second driving transistor DT2 of the blue (B) subpixel, and a slope of a graph may be relatively large.

However, according to the present disclosure, as described above with reference to FIG. 3, in the first subpixel SP1 emitting green (G) light, the thicknesses of the first and second device buffer layers 141 and 142 of the first driving transistor DT1 may be adjusted, and thus, an S-factor SFg′ of the first driving transistor DT1 may be enhanced to be higher than an S-factor SFb of the second driving transistor DT2, whereby a slope of a graph may be gently-sloped from SFg to SFg′.

In detail, as described above with reference to FIG. 3, in the first device buffer layer 141 including SiOx, a capacitance of a capacitor of the first device buffer layer 141 may increase as a thickness thereof decreases, and as the thickness thereof increases, the capacitance of the capacitor of the first device buffer layer 141 may decrease.

In the second device buffer layer 142 including SiNx, a capacitance of a capacitor of the second device buffer layer 142 may increase as a thickness thereof increases, and as the thickness thereof decreases, the capacitance of the capacitor of the second device buffer layer 142 may decrease.

Accordingly, buffer capacitances C1b and C2b of the device buffer layer 140 including the first and second device buffer layers 141 and 142 may increase as a thickness of the first device buffer layer 141 decreases, and moreover, may increase as a thickness of the second device buffer layer 142 increases.

Moreover, an S-factor of each of the first and second driving transistors DT1 and DT2 may be determined based on a ratio of first and second gate capacitances C1a and C2a between the gate electrodes G1 and G2 and the semiconductor layers ACT1 and ACT2 and first and second buffer capacitances C1b and C2b between the semiconductor layers ACT1 and ACT2 and the metal layers LS1 and LS2.

In detail, the S-factor SFg of the first driving transistor DT1 may increase as the first buffer capacitance C1b increases, with respect to the first gate capacitance C1a, and the S-factor SFb of the second driving transistor DT2 may increase as the second buffer capacitance C2b increases, with respect to the second gate capacitance C2a.

The first and second gate capacitances C1a and C2a may be determined based on a thickness of the second gate insulation layer 150, and as in FIG. 3, thicknesses of the second gate insulation layers 150 of the first and second driving transistors DT1 and DT2 may be equal to each other, and thus, the first and second gate capacitances C1a and C2a may have the same value.

Accordingly, the S-factor SFg of the first driving transistor DT1 and the S-factor SFb of the second driving transistor DT2 may increase as the first and second gate capacitances C1a and C2a increase.

In the present disclosure, under the first driving transistor DT1, the thickness TGB1 of the first device buffer layer 141 may be less than the thickness TBB1 of the first device buffer layer 141 of the second driving transistor DT2, and the thickness TGB2 of the second device buffer layer 142 may be greater than the thickness TBB2 of the second device buffer layer 142 of the second driving transistor DT2, and thus, the first buffer capacitance C1b of the first driving transistor DT1 may be greater than the second buffer capacitance C2b of the second driving transistor DT2.

Accordingly, in the present disclosure, the S-factor of the first driving transistor DT1 may be enhanced to be higher than the S-factor of the second driving transistor DT2.

As described above, in the present disclosure, thicknesses of the first and second device buffer layers 141 and 142 may be adjusted by using a relationship between an S-factor and each of a gate capacitor and a buffer capacitor, and thus, the S-factor SFg′ of the first driving transistor DT1 targeted among the first and second driving transistors DT1 and DT2 may be enhanced to be higher than the S-factor SFb of the second driving transistor DT2.

Therefore, the gray expression of the first subpixel SP1 may be more stabilized by the first driving transistor DT1.

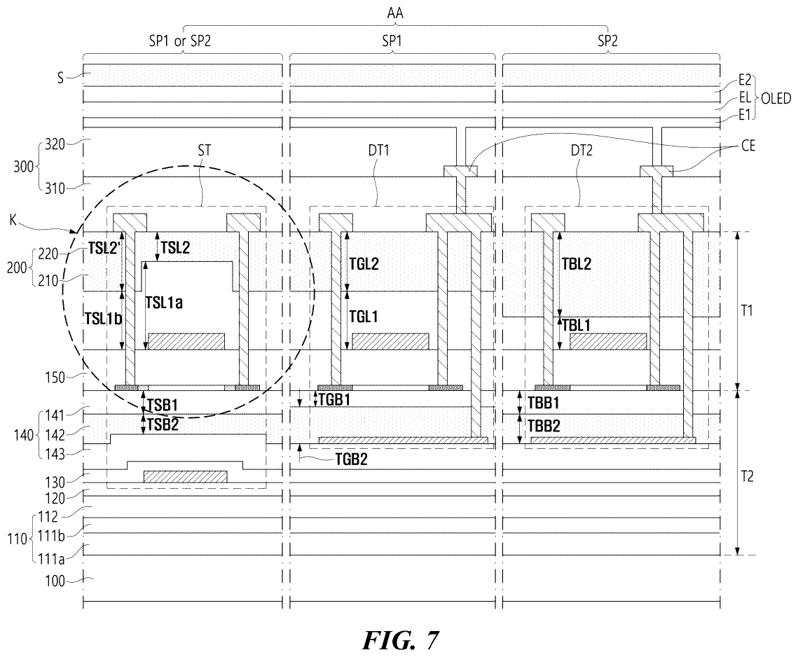

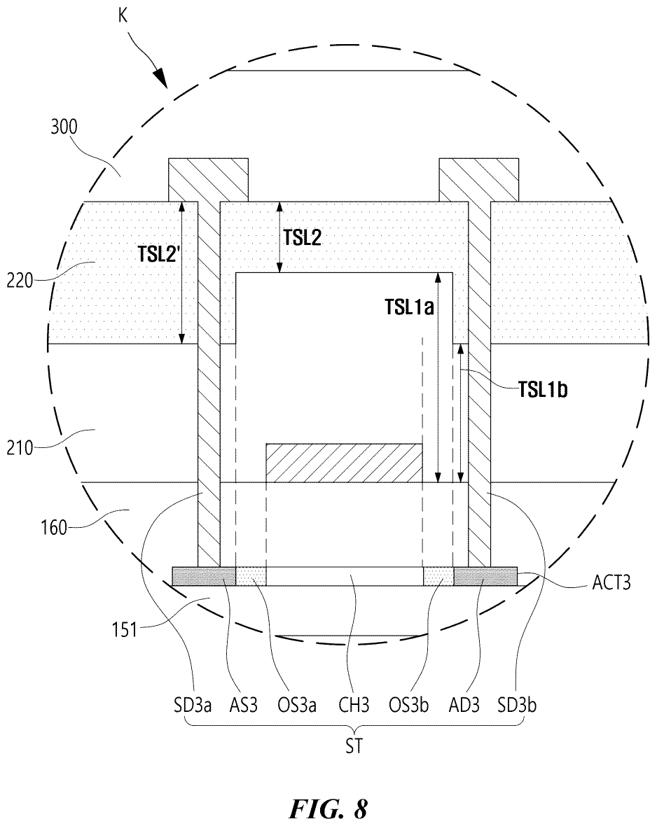

FIGS. 7 and 8 are diagrams for describing an embodiment of an interlayer structure of a display panel including a switching transistor and a driving transistor according to a second embodiment of the present disclosure. FIG. 8 is an enlarged view of area K in FIG. 7.

Hereinafter, in describing FIG. 7, descriptions overlapping the descriptions of FIGS. 1 to 6 may be briefly given or replaced with the above description, and a difference therebetween will be mainly described.

A switching transistor ST may include low concentration regions OS3a and OS3b, so as to decrease a leakage current in an off state and contribute to the control and stabilization of a threshold voltage Vth thereof.

For example, as illustrated in FIG. 8, a third semiconductor layer ACT3 of the switching transistor ST may include a third channel region CH3, third conductive regions AS3 and AD3, and the low concentration regions OS3a and OS3b.

The third channel region CH3 may have a lowest hydrogen concentration in the third semiconductor layer ACT3, or may be hardly doped with hydrogen. The third conductive regions AS3 and AD3 may be higher in hydrogen concentration than the third channel region CH3. The low concentration regions OS3a and OS3b may have a hydrogen concentration between the third channel region CH3 and the third conductive regions AS3 and AD3.

Here, one of the third conductive regions AS3 and AD3 may be a third source region AS3, and the other may be a third drain region AD3.

The third channel region CH3 may overlap a third gate electrode G3 of the switching transistor ST, the low concentration regions OS3a and OS3b may be disposed in a region, which does not overlap the third gate electrode G3 of the switching transistor ST, of the third semiconductor layer ACT3 of the switching transistor ST, and the third conductive regions AS3 and AD3 may be disposed outside the low concentration regions OS3a and OS3b in the third semiconductor layer ACT3 of the switching transistor ST.

In the second embodiment, as in FIG. 8, a thickness TSL1a of a portion, overlapping the low concentration regions OS3a and OS3b of the switching transistor ST, of a first upper interlayer insulation layer 210 may be greater than a thickness TSL1b of a portion, overlapping the third conductive regions AS3 and AD3, of the first upper interlayer insulation layer 210.

For example, as in FIG. 7, the thickness TSL1a of the portion, overlapping the low concentration regions OS3a and OS3b of the switching transistor ST, of the first upper interlayer insulation layer 210 may be greater than thicknesses TGL1 and TBL1 of portions of the first upper interlayer insulation layer 210 disposed on the first and second semiconductor layers ACT1 and ACT2 of the first and second driving transistors DT1 and DT2.

Moreover, for example, a thickness TSL1b of a portion, overlapping the third conductive regions AS3 and AD3 of the switching transistor ST, of the first upper interlayer insulation layer 210 may be equal to the thickness TGL1 of the portion disposed on the first semiconductor layer ACT1 of the first driving transistor DT1.

Moreover, a thickness TSL2 of a portion, overlapping the low concentration regions OS3a and OS3b of the switching transistor ST, of a second upper interlayer insulation layer 220 may be less than a thickness TSL2′ of a portion, overlapping the third conductive regions AS3 and AD3, of the second upper interlayer insulation layer 220.

The thickness TSL2′ of the portion, overlapping the third conductive regions AS3 and AD3, of the second upper interlayer insulation layer 220 may be equal to the thickness TSL2 of the second upper interlayer insulation layer 220 of the first driving transistor DT1.

According to the present disclosure, as in FIGS. 7 and 8, the thickness TSL1a of the portion, overlapping the low concentration regions OS3a and OS3b of the switching transistor ST, of the first upper interlayer insulation layer 210 may be relatively large, and the thickness TSL1b of the portion, overlapping the third conductive regions AS3 and AD3, of the first upper interlayer insulation layer 210 may be relatively small, and thus, the low concentration regions OS3a and OS3b of the switching transistor ST may be doped with hydrogen at a concentration which is lower than the third conductive regions AS3 and AD3 of the switching transistor ST, in an annealing process.

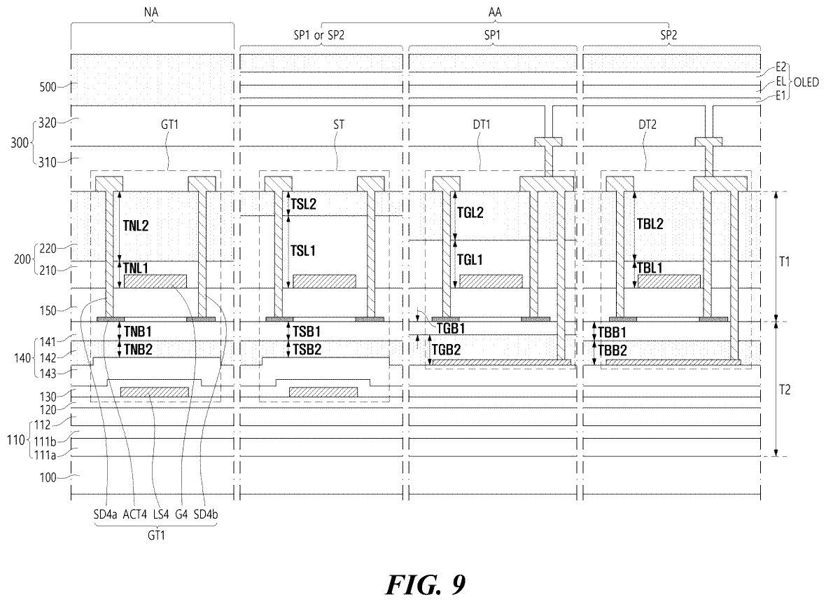

FIG. 9 is a diagram for describing an embodiment of an interlayer structure of a display panel including a transistor provided in a non-active area NA compared to a transistor provided in an active area AA, according to a first embodiment of the present disclosure.

As illustrated in FIG. 9, a GIP transistor GT1 may be included in a non-active area NA of a display panel 10.

The GIP transistor GT1 may include a fourth gate electrode G4, a fourth semiconductor layer ACT4, a fourth source electrode SD4a, a fourth drain electrode SD4b, and a fourth metal layer LS4.

The fourth gate electrode G4 may be disposed between a first upper interlayer insulation layer 210 and a second gate insulation layer 150 and may include the same conductive material as that of first to third gate electrodes G1 to G3.

A fourth semiconductor layer ACT4 may be disposed between the second gate insulation layer 150 and a first device buffer layer 141 and may include an oxide semiconductor.

The fourth source electrode SD4a and the fourth drain electrode SD4b may be disposed between a second upper interlayer insulation layer 220 and a first planarization layer 310 and may include the same conductive material as that of each of first to third drain electrodes SD1b, SD2b, and SD3b and first to third source electrodes SD1a, SD2a, and SD3a.

The fourth metal layer LS4 may be disposed between a first gate insulation layer 120 and a lower interlayer insulation layer 130 and may overlap the fourth semiconductor layer ACT4. The fourth metal layer LS4 may block external light incident on the fourth semiconductor layer ACT4, and although not shown, may be electrically connected to the fourth gate electrode G4. Accordingly, the fourth metal layer LS4 may function as a bottom gate electrode. The fourth metal layer LS4 may include the same material as that of the third metal layer LS3 and may include a conductive material which differs from that of each of the first and second metal layers LS1 and LS2.

In the GIP transistor GT1, a thickness TNL1 of the first upper interlayer insulation layer 210 disposed on the fourth semiconductor layer ACT4 may differ from a thickness TSL1 of the first upper interlayer insulation layer 210 of the switching transistor ST, and a thickness TNL2 of the second upper interlayer insulation layer 220 of the GIP transistor GT1 may differ from a thickness TSL2 of the second upper interlayer insulation layer 220 of the switching transistor ST.

For example, the thickness TNL1 of the first upper interlayer insulation layer 210 of the GIP transistor GT1 may be less than the thickness TSL1 of the first upper interlayer insulation layer 210 of the switching transistor ST, and the thickness TNL2 of the second upper interlayer insulation layer 220 of the GIP transistor GT1 may be greater than the thickness TSL2 of the second upper interlayer insulation layer 220 of the switching transistor ST.

For example, the thickness TNL1 of the first upper interlayer insulation layer 210 of the GIP transistor GT1 may be equal to a thickness TBL1 of a first upper interlayer insulation layer 210 of the second driving transistor DT2 included in a second subpixel SP2 emitting blue or red light. Furthermore, a thickness of the second upper interlayer insulation layer 220 of the GIP transistor GT1 may be equal to a thickness TBL2 of the second upper interlayer insulation layer 220 of the second driving transistor DT2.

Moreover, in the GIP transistor GT1, the thickness TNL2 of the second upper interlayer insulation layer 220 may be greater than the thickness TNL1 of the first upper interlayer insulation layer 210.

As described above, based on a structure including the first and second upper interlayer insulation layers 210 and 220 of the GIP transistor GT1, the fourth semiconductor layer ACT4 of the GIP transistor GT1 may be doped with hydrogen at a high concentration, and a reaction speed of the GIP transistor GT1 may be enhanced.

Moreover, a thickness TNB1 of a first device buffer layer 141 of the GIP transistor GT1 may be equal to a thickness TSB1 of a first device buffer layer 141 of the switching transistor ST, and a thickness TNB2 of a second device buffer layer 142 of the GIP transistor GT1 may be equal to a thickness TSB2 of a second device buffer layer 142 of the switching transistor ST.

Therefore, a concentration of hydrogen doped in the fourth semiconductor layer ACT4 of the GIP transistor GT1 may be relatively high, and thus, a reaction speed of the GIP transistor GT1 may be enhanced.

As described above, for example, the GIP transistor GT1 may be used in a buffer or a scan driver which supplies a scan signal to a plurality of subpixels SP.

Moreover, depending on the case, the display panel 10 according to the present disclosure may further include a low temperature polycrystalline silicone (LTPS) transistor. Hereinafter, an example where the display panel 10 according to the present disclosure further includes an LTPS transistor will be described.

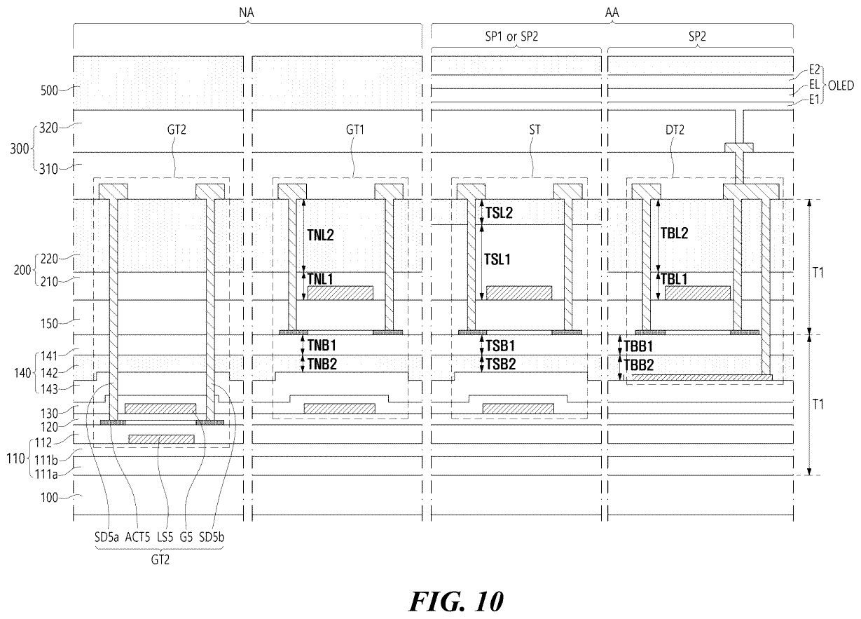

FIG. 10 is a diagram for describing an embodiment of an interlayer structure of a display panel including an LTPS transistor capable of being further provided in a non-active area, according to an embodiment of the present disclosure.

Referring to FIG. 10, a display panel 10 according to an embodiment of the present disclosure may further include an LTPS transistor GT2 in a non-active region NA.

In the present disclosure, for convenience of description, an example where the LTPS transistor GT2 is included in the non-active region NA may be described, but the present disclosure is not limited thereto and depending on the case, the LTPS transistor GT2 may be included in a subpixel SP of an active region AA of the display panel 10.

The LTPS transistor GT2, as illustrated in FIG. 10, may include a fifth gate electrode G5, a fifth semiconductor layer ACT5, a fifth source electrode SD5a, a fifth drain electrode SD5b, and a fifth metal layer LS5.

The fifth gate electrode G5 may be disposed between a first gate insulation layer 120 and a lower interlayer insulation layer 130 and may include the same conductive material as that of each of the third and fourth metal layers LS3 and LS4.

The fifth semiconductor layer ACT5 may be disposed between the first gate insulation layer 120 and an active buffer layer 112 and may include an LTPS semiconductor material, and moreover, a dopant differing from hydrogen may be doped thereon.

The fifth source electrode SD5a and the fifth drain electrode SD5b may be disposed between a second upper interlayer insulation layer 220 and a first planarization layer 310 and may include the same conductive material as that of each of first to fourth source electrodes SD1a, SD2a, SD3a, and SD4a and first to fourth drain electrodes SD1b, SD2b, SD3b, and SD4b.

Each of the fifth source electrode SD5a and the fifth drain electrode SD5b may pass through up to the first gate insulation layer 120 from the upper interlayer insulation layer 200 and may contact a fifth semiconductor layer ACT5.

The fifth metal layer LS5 may be disposed between the active buffer layer 112 and a second multi buffer layer 111b and may block external light incident on the fifth semiconductor layer ACT5, and depending on the case, the fifth metal layer LS5 may be electrically connected to a constant voltage source.

As described above, in embodiments of the present disclosure, in the switching transistor ST requiring a relatively short channel length in each subpixel SP, a thickness of the first upper interlayer insulation layer 210 may be set to be relatively large, and a thickness of the second upper interlayer insulation layer 220 may be set to be relatively small, and thus, a concentration of hydrogen doped in a semiconductor layer of the switching transistor ST may be reduced, thereby maximizing a channel of the switching transistor ST and allowing a threshold voltage (Vth) of the switching transistor ST to be positive-shifted (+shifted).

In embodiments of the present disclosure, in the first driving transistor DT1 requiring relatively stable gray expression in each subpixel SP, a thickness of the first device buffer layer 141 may be set to be relatively small, and a thickness of the second device buffer layer 142 may be set to be relatively large, and thus, an S-factor of the first driving transistor DT1 may increase, thereby more stabilizing the gray expression of a unit pixel.

In embodiments of the present disclosure, in the second driving transistor DT2 requiring a relatively high on current (Ion) characteristic in each subpixel SP, a thickness of the first upper interlayer insulation layer 210 may be set to be relatively small, and a thickness of the second upper interlayer insulation layer 220 may be set to be relatively large, and thus, a concentration of hydrogen doped in a semiconductor layer of each of the driving transistors DT1 and DT2 may increase, thereby responding to a high on current (Ion) characteristic of a semiconductor layer of the second driving transistor DT2 and decreasing power consumption.

In embodiments of the present disclosure, in a switching transistor requiring a relatively short channel length in each subpixel, a thickness of a first upper interlayer insulation layer may be set to be relatively large, and a thickness of a second upper interlayer insulation layer may be set to be relatively small, and thus, a concentration of hydrogen doped in a semiconductor layer of the switching transistor may be reduced, thereby maximizing a channel of the switching transistor and allowing a threshold voltage (Vth) of the switching transistor to be positive-shifted (+shifted).

In embodiments of the present disclosure, in a first driving transistor requiring relatively stable gray expression in each subpixel, a thickness of a first device buffer layer may be set to be relatively small, and a thickness of a second device buffer layer may be set to be relatively large, and thus, an S-factor of the first driving transistor may increase, thereby more stabilizing the gray expression of a unit pixel.

In embodiments of the present disclosure, in a second driving transistor requiring a relatively high on current (Ion) characteristic in each subpixel, a thickness of a first upper interlayer insulation layer may be set to be relatively small, and a thickness of a second upper interlayer insulation layer may be set to be relatively large, and thus, a concentration of hydrogen doped in a semiconductor layer of a driving transistor may increase, thereby responding to a high on current (Ion) characteristic of a semiconductor layer of the second driving transistor and decreasing power consumption.

Embodiments of the present disclosure may enhance the power consumption of a transistor and may decrease the power consumption of a display apparatus, thereby implementing ESG.

The effects according to the present disclosure are not limited to the above examples, and other various effects may be included in the specification.

While the present disclosure has been particularly shown and described with reference to exemplary embodiments thereof, it will be understood by those of ordinary skill in the art that various changes in form and details may be made therein without departing from the spirit and scope of the present disclosure as defined by the following claims.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display panel comprising:
a substrate including an active area and a non-active area;
a driving transistor configured to supply a driving current to a light emitting device disposed in a subpixel of the active area, the driving transistor including a gate electrode and a semiconductor layer including oxide;
a switching transistor disposed in the subpixel, electrically connected to the driving transistor, the switching transistor including a gate electrode and a semiconductor layer including oxide;
a first upper interlayer insulation layer disposed respectively on the semiconductor layers of the driving transistor and the switching transistor; and
a second upper interlayer insulation layer disposed on the first upper interlayer insulation layer,
wherein a thickness of the first upper interlayer insulation layer disposed on the semiconductor layer of the switching transistor differs from a thickness of the first upper interlayer insulation layer disposed on the semiconductor layer of the driving transistor.

2. The display panel of claim 1, wherein the thickness of the first upper interlayer insulation layer disposed on the switching transistor is greater than the thickness of the first upper interlayer insulation layer disposed on the driving transistor.

3. The display panel of claim 1, wherein a thickness of the second upper interlayer insulation layer disposed on the switching transistor differs from a thickness of the second upper interlayer insulation layer disposed on the driving transistor.

4. The display panel of claim 3, wherein the thickness of the second upper interlayer insulation layer disposed on the switching transistor is less than the thickness of the second upper interlayer insulation layer disposed on the driving transistor.

5. The display panel of claim 1, wherein a hydrogen content of the second upper interlayer insulation layer is higher than a hydrogen content of the first upper interlayer insulation layer.

6. The display panel of claim 1, wherein the first upper interlayer insulation layer and the second upper interlayer insulation layer comprise different insulating materials, and
wherein the first upper interlayer insulation layer comprises silicone oxide, and the second upper interlayer insulation layer comprises silicone nitride.

7. The display panel of claim 1, wherein the second upper interlayer insulation layer disposed on the switching transistor and the second upper interlayer insulation layer disposed on the driving transistor lie in a common plane.

8. The display panel of claim 1, wherein the driving transistor comprises:
a first driving transistor disposed in a first subpixel and configured to supply a driving current to a first light emitting device emitting light of a first color; and
a second driving transistor disposed in a second subpixel and configured to supply a driving current to a second light emitting device emitting light of a second color differing from the first color,
wherein a thickness of each of the first and second upper interlayer insulation layers disposed on the first driving transistor differs from a thickness of each of the first and second upper interlayer insulation layers disposed on the second driving transistor.

9. The display panel of claim 8, wherein the first light emitting device emits green light, and the second light emitting device emits blue or red light, and
a thickness of the first upper interlayer insulation layer disposed on the first driving transistor is greater than a thickness of the first upper interlayer insulation layer disposed on the second driving transistor.

10. The display panel of claim 8, wherein a thickness of the second upper interlayer insulation layer disposed on the second driving transistor is greater than a thickness of the second upper interlayer insulation layer disposed on the first driving transistor.

11. The display panel of claim 8, further comprising a device buffer layer, the device buffer layer comprises:
a first device buffer layer disposed under the semiconductor layer included in each of the switching transistor and the first and second driving transistors to contact the semiconductor layer; and
a second device buffer layer disposed under the first device buffer layer, and
wherein the first and second device buffer layers have different dielectric constants.

12. The display panel of claim 11, wherein a thickness of the first device buffer layer disposed under the first driving transistor differs from a thickness of the first device buffer layer disposed under the second driving transistor.

13. The display panel of claim 11, wherein a thickness of the first device buffer layer disposed under the first driving transistor is less than a thickness of the first device buffer layer disposed under the second driving transistor.

14. The display panel of claim 11, wherein the semiconductor layer of the switching transistor and the semiconductor layer included in each of the first and second driving transistors are disposed on the first device buffer layer lie in a common plane.

15. The display panel of claim 11, wherein a thickness of the second device buffer layer disposed under the first driving transistor differs from a thickness of the second device buffer layer disposed under the second driving transistor.

16. The display panel of claim 15, wherein the thickness of the second device buffer layer disposed under the first driving transistor is greater than the thickness of the second device buffer layer disposed under the second driving transistor.

17. The display panel of claim 11, wherein a thickness of the first device buffer layer is less than a thickness of the second device buffer layer, under the first driving transistor.

18. The display panel of claim 11, wherein the first device buffer layer and the second device buffer layer comprise different insulating materials, and
the first device buffer layer comprises silicone oxide, and the second device buffer layer comprises silicone nitride.

19. The display panel of claim 1, wherein the semiconductor layer of the switching transistor comprises a channel region, a conductive region which is higher in hydrogen concentration than the channel region, and a low concentration region having a hydrogen concentration between the channel region and the conductive region,
wherein the channel region overlaps a gate electrode of the switching transistor,
wherein the low concentration region is positioned in a region, which does not overlap the gate electrode of the switching transistor, of the semiconductor layer of the switching transistor, and
wherein the conductive region is positioned outside the low concentration region in the semiconductor layer of the switching transistor.

20. The display panel of claim 19, wherein a thickness of a portion, overlapping the low concentration region, of the switching transistor in the first upper interlayer insulation layer is greater than a thickness of a portion, overlapping the conductive region, of the switching transistor.

21. The display panel of claim 19, wherein a thickness of a portion, overlapping the low concentration region, of the switching transistor in the first upper interlayer insulation layer is greater than a thickness of the first upper interlayer insulation layer disposed on the semiconductor layer of the driving transistor.

22. The display panel of claim 1, further comprising a Gate-In-Panel (GIP) transistor including a gate electrode and a semiconductor layer including oxide, in the non-active area,
wherein a thickness of the first upper interlayer insulation layer disposed on the GIP transistor differs from a thickness of the first upper interlayer insulation layer disposed on the switching transistor.

23. The display panel of claim 22, wherein the thickness of the first upper interlayer insulation layer disposed on the GIP transistor is less than the thickness of the first upper interlayer insulation layer disposed on the switching transistor.

24. The display panel of claim 22, wherein a thickness of the second upper interlayer insulation layer disposed on the GIP transistor differs from a thickness of the second upper interlayer insulation layer disposed on the switching transistor.

25. The display panel of claim 22, wherein the thickness of the second upper interlayer insulation layer disposed on the GIP transistor is greater than the thickness of the second upper interlayer insulation layer disposed on the switching transistor.
